(19) United States
(12) Patent Application Publication
(10) Pub. No.: US 2011/0220025 A1
(43) Pub. Date: Sep. 15, 2011

(54) METAL ORGANIC CHEMICAL VAPOR DEPOSITION APPARATUS HAVING SATELLITE N-TYPE AND P-TYPE DOPING CHAMBERS

(76) Inventors: Weon Guk JEONG, Suwon-si (KR); Hee Kyung HAN, Suwon-si (KR)

(21) Appl. No.: 13/040,231

(22) Filed: Mar. 3, 2011

(30) Foreign Application Priority Data
Mar. 15, 2010 (KR) 10-2010-0022581

(51) Int. Cl. H01L 21/04

(52) U.S. Cl. 118/719

(57) ABSTRACT

The present invention is related to a metal organic chemical vapor deposition apparatus, which is equipped with multiple numbers of n-type doping satellite chambers and a p-type doping satellite chamber in addition to a main growth chamber, and methods for minimizing the contamination of the epitaxial layers by residual doping reactants and maximizing the productivity of wafers. The separate n-type doping, p-type doping, and main growth chambers minimize the contamination of the growing epitaxial layer by the reactants used for doping the layer in the previous growth steps and deposited inside of the chamber. The multiple n-type doping satellite chambers make it possible to schedule the start of growth in each chamber in a way that the growth finishes at a regular time interval so that the wafers can be transferred to the main chamber at a regular time interval. They also make it possible to allocate one of the chambers for chamber cleaning and maintenance while the other chambers are in operation so that the growth process is not interrupted. The present invention can most efficiently be utilized for the growth of epitaxial wafers for GaN-based light emitting diodes.

### CROSS-REFERENCE TO RELATED APPLICATION

This application claims priority to and the benefit of Korean Patent Application No. 2010-0022581, filed on Mar. 15, 2010, the disclosure of which is incorporated herein by reference in its entirety.

### BACKGROUND

1. Field of the Invention

The present invention is related to a metal organic chemical vapor deposition (MOCVD) apparatus and methods, and more particularly, to an MOCVD apparatus which is equipped with satellite n-type and p-type doping chambers in addition to a main growth chamber and methods of operation of the apparatus for minimizing contamination by n-type and p-type doping of the growing layers by residual doping reactants deposited inside of the chamber during epitaxial growth of gallium nitride (GaN) based compound semiconductors and for maximizing the productivity of epitaxial wafers by minimizing the interruption on wafer production by chamber cleaning and maintenance of the reactor.

2. Discussion of Related Art

The light emitting diodes (LEDs) typically have a multilayer structure, in which n-type doped layer, active layer, and p-type doped layer are epitaxially grown on a substrate. For example, typical gallium nitride (GaN) based LEDs are grown to have epitaxial layers of undoped GaN layer, n-type doped GaN layer, indium gallium nitride (InGaN) active layer or InGaN/GaN multiquatum well (MQW) active layer, p-type aluminum gallium nitride (AlGaN) layer, and p-type GaN layer in sequence on a sapphire substrate. The layers with other chemical composition such as indium aluminum gallium nitride (InAlGaN), aluminum nitride (AlN), and indium nitride (InN) are also used as constituent layers for the device in some cases.

In conventional MOCVD methods, the epitaxial structure is typically grown in a single chamber. An epitaxial growth process using a conventional MOCVD chamber will now be described in detail. The process includes the steps of supplying reactants, which contain constituent atomic elements of the respective layers of the structure, to the chamber, heating the supplied reactants through a wafer-carrier (or susceptor), and depositing the chemical elements through thermal decomposition and chemical reactions of the reactants. For example, trimethylgallium (TMGa) and ammonia (NH₃) are supplied to the chamber so that GaN epitaxial layer can be grown on a wafer.

During the flow of reactants in the chamber, the supplied reactants are decomposed and deposited on the wafer and epitaxial layers are grown on it. In addition, they may also be deposited and remain in several parts inside of the chamber. For example, the supplied reactants may be deposited on a chamber wall, the surface of a shower-head, reactant inlet tubings, a wafer-carrier, and exhaust tubings.

A part of the reactants deposited on various parts inside of the chamber described above may not stay there for long period of time but evaporate into the gas phase and be mixed with subsequently supplied reactants and then incorporated into the layers that are being grown in the following steps. This mixing of reactants is not desirable since the reactants supplied for the growth of previous layer are not the ones planned for the growth of a new layer. Therefore, this mixing contaminates the layer that is being grown in the following step. For example, when the whole planned layers are grown on a wafer, the wafer is unloaded from the chamber, and a new wafer is loaded into the chamber, and a new growth is started by growing undoped GaN layer, n-type doped GaN layer and so on. In this case, since the p-type GaN-based layer was grown in the final step during the growth of the previous LED wafer, the p-type reactant that had been deposited inside of the chamber and evaporated is mixed with newly supplied reactants and incorporated into the growing undoped or n-type doped GaN layers.

Then the undoped layer can be slightly p-type doped, which is not intended, and the electrical property of n-type doped GaN layer can be deteriorated since the p-type reactant introduces opposite electrical polarity to the n-type GaN layer. As is known, this contamination of the undoped and n-type GaN layer with the p-type reactant occurs relatively easily with biscyclopentadienyl magnesium (Cp₂Mg) which is the most widely used p-type doping reactant for GaN-based semiconductors.

As another example, when undoped multiple quantum well (MQW) layer is grown on n-type doped layer, the n-type doping reactant which had been deposited on various parts inside of the chamber may evaporate into the gas phase and be incorporated into the MQW layer. Then the background doping concentration of the MQW layer can be undesirably high.

In addition to the doping contamination, there is a particle generation problem in the growth of GaN layer by MOCVD. When TMGa and NH3 are supplied into the growth chamber, they form epitaxial layer on a substrate. However, they also generate small particles in the gas phase and the particles stick on various parts inside of the chamber. The number of particles formed depends on the growth conditions such as the growth pressure and temperature. The particles sometimes fall onto the surface of the growing layer and deteriorate the morphology of the wafer and reduce the productivity of the process in doing so.

In order to solve the problems related to the above mentioned doping contamination and particle generation-and-falling, a few methods are usually adopted. The coating of the inside of the chamber including the wafer-carrier, while the wafers are not loaded in the chamber, with GaN film by supplying TMGa and NH₃ into the chamber and heating the reactor is sometimes used to mitigate doping contamination problem. In addition to GaN coating, after a certain number of wafer growth runs with the reactor, the growth chamber is opened and the inside of the chamber is cleaned. The manual wiping-out of the residual reactants and particles is one of the commonly used methods to reduce doping contamination and to remove particles.

However, these coating and cleaning processes interrupt the wafer production process and thus lead to a reduction in productivity of the apparatus.

Out of several other disclosed techniques proposed for solving doping contamination of the chamber, there are U.S. Pat. No. 7,368,368 and U.S. Patent Publication No. 2005/0115492.

In brief, U.S. Pat. No. 7,368,368 proposes a method of transferring the wafer grown in n-type chamber to p-type chamber to grow p-type layers and then transferring the wafer back to the n-type chamber to grow n-type layers on top of p-type layers. In this way, the wafer can be moved back and forth between two chambers depending on the electrical type of the layers to be grown and the cross-contamination between the n-type doping and the p-type doping could be reduced since the n-type doping and p-type doping are performed in separate chambers as compared to the case where layers with two different electrical types are grown in the same chamber. However, in this case, since one of two chambers should stay idling by not being used for growth while the growth proceeds in the other chamber, the method always introduces idling time for one chamber and thus leads to inefficient use of the chambers.

U.S. Patent Publication No. US2005/0115492 proposes a method for maximizing the usage of chambers using multiple numbers of chambers and distributing the growth time evenly among the chambers. For example, when it takes four hours to grow n-type doped layer and one hour to grow p-type doped layer, four n-type chambers and one p-type chamber are installed in a row and the wafer is grown in each of five chambers for one hour. That is, the wafer is grown for one hour and transferred to the next chamber in every one hour. However, in this method, one wafer should sequentially pass through five chambers so that an extra time can be required for each transfer process, thereby increasing the time for the entire epitaxial growth process. That is, even when one single n-type layer is being grown, the wafer should sequentially pass through four chambers and this process increases the total growth time.

Furthermore, since the wafer transfer chamber or the load-lock chamber is shared by all growth chambers for two disclosed methods described above, the probability of the chambers being cross-contaminated with one another through robot-arms is increased.

Specifically, it is highly likely that the chambers may be contaminated by robot-arms which get in and out of all chambers and thus stained with residual reactants. Also, when the gate valve is opened, the corresponding growth chamber and the wafer transfer chamber are open to each other. In this case, since the gas could flow from the growth chamber to the wafer transfer chamber, the wafer transfer chamber can be contaminated with reactant gases that had been deposited inside of the growth chamber and supplied from it. Then the n-type and p-type growth chamber can be cross-contaminated through the contaminated wafer-transfer chamber.

Therefore, the cross-contamination problem still remains unsolved even with the above-described methods, and it is still needed to develop a new MOCVD apparatus.

### SUMMARY OF THE INVENTION

According to an aspect of the present invention, an MOCVD apparatus includes: multiple numbers of first-doping-type satellite chambers configured to grow first-doping-type semiconductor layers on a wafer; a first wafer transfer chamber connected to the first-doping-type satellite chambers, and is equipped with a robot configured to transfer wafers; a main chamber connected to the first wafer transfer chamber, and configured to grow semiconductor layers on the first-doping-type semiconductor layer; a second wafer transfer chamber connected to the main chamber, and equipped with a robot configured to transfer wafers; and at least one second-doping-type satellite chamber connected to the second wafer transfer chamber, and configured to grow second-doping-type semiconductor layers on the wafer. Here, the first-doping-type satellite chambers, the first wafer transfer chamber, the main chamber, and the second-doping-type satellite chamber are configured to allow the wafer to be sequentially transferred in forward direction only and the transfer of wafers in reverse direction is not assumed to be used unless specifically planned.

The MOCVD apparatus may include at least two first-doping-type satellite chambers. In this case, by scheduling the start of the growth in each of the first-doping-type satellite chambers, the transfer of wafers from the first-doping-type satellite chamber to the main chamber can be made at regular intervals so that the usage of the main chamber and the second-doping-type chamber for growth can be made maximum. When the growth in one of the first-doping-type satellite chamber is started when the growth in the other first-doping-type satellite chamber has proceeded about a half of the full growth time, and if this scheme is repeated with two first-doping-type satellite chambers, the time interval between the ends of the growth in the first-doping-type satellite chambers can be regularly controlled. Then the transfer of wafers to the main chamber can be made at a regular time interval so that the idling time for the main chamber for growth can be made to a minimum.

The MOCVD apparatus may include at least three first-doping-type satellite chambers. The first-doping-type satellite chambers perform a growth process at predetermined time intervals among chambers similar to the procedure as described above and transfer wafers to the main chamber sequentially at a regular time interval. In this configuration, while two of the first-doping-type satellite chambers are performing the growth process, the remaining chamber(s) can be allocated for chamber cleaning or maintenance processes.

The MOCVD apparatus may further include load-lock chambers in front of the first-doping-type growth chambers. Each of the load-lock chambers store wafers on which the epitaxial growth process will begin in the main chamber, and are equipped with a robot configured to transfer wafers. Also, the valves are installed between each pair of the load-lock chamber and the first-doping-type satellite chamber.

The MOCVD apparatus may further include a load-lock chamber after the second-type-doping growth chamber. The load-lock chamber stores wafers on which the growth process has been finished and is equipped with a robot configured to transfer wafers.

The MOCVD apparatus of the present invention can be efficiently operated when the growth time for the first-doping-type semiconductor layer is about twice the time needed to grow a semiconductor layer in the main chamber. Then three first-doping-type satellite chambers and one main chamber are provided, and two of the first-doping-type satellite chambers are operated to grow first-doping-type semiconductors, and the remaining one first-doping-type satellite chamber is allocated for chamber cleaning or maintenance processes.

The MOCVD apparatus of the present invention can also be efficiently operated even when the growth time for the first-doping-type semiconductor layer is shorter than twice the time needed to grow a semiconductor layer in the main chamber. Then at least two first-doping-type satellite chambers are provided, and one of the first-doping-type satellite chambers is operated for the growth of semiconductor layers, and the other satellite chamber is allocated for chamber cleaning and maintenance processes when needed.

In the MOCVD apparatus of the present invention, the doping satellite chambers are installed mainly to perform doping growth processes.

For instance, n-type doped layers are mostly grown in the n-type doping satellite chamber, and p-type doped layers are mostly grown in the p-type doping satellite chamber. However, undoped layers can also be grown in either of the n-type and p-type doping satellite chambers when desired.

The growth process in the MOCVD apparatus of the present invention can proceed as follows: The first batch of wafers is loaded into the n-type doping satellite chamber to grow n-type doped layers on a wafer. Thereafter, when the growth process is finished in the n-type doping satellite chamber, the wafers are transferred to the main chamber through the wafer transfer chamber and the next growth process are performed in the main chamber. When the first batch of wafers is unloaded from the n-type doping satellite chamber, the second batch of wafers is loaded into the n-type doping satellite chamber and a new growth process is started.

When the growth process is finished on the first batch of wafers in the main chamber, the wafers are transferred to the p-type doping satellite chamber and the growth process is continued. Meanwhile, when the growth process is finished in the n-type doping satellite chamber in which the second batch of wafers had been inserted, the wafers are transferred to the main chamber and the growth process is continued. Thereafter, the third batch of wafers is loaded into the n-type doping satellite chamber and a new growth process is started.

After a batch of wafers is loaded, layers are sequentially grown in the n-type doping satellite chamber, the main chamber, and the p-type doping satellite chamber. Depending on the layer structure to be grown, the n-type and p-type growth processes may be partially performed in the main chamber. However, since the MOCVD apparatus in this invention is equipped with separate doping satellite chambers, the doping growth process in the main chamber can be minimized.

Furthermore, multiple numbers of doping satellite chambers can be installed depending on the growth times of the constituent layers in the whole layer structure. In a typical growth process of GaN-based LEDs, it takes much longer time for the growth of the layers below the active layer than for other layers in the structure. This is because thick undoped GaN and n-type doped GaN layer are usually grown on a sapphire substrate first in order to reduce crystal defects caused by the difference in lattice constant between the GaN layer and the sapphire substrate.

Typically, it takes about four hours to grow GaN-based layers before the start of the growth of active layer, and it takes about two hours to grow the active layer, and it takes about two hours or less to grow layers on top of the active layer and cool down the wafer to unload the wafer from the chamber. In this case, two n-type doping satellite chambers can be installed to balance the growth time in the n-type doping satellite chamber with those in the main chamber and p-type doping satellite chamber.

In this case, a batch of wafers is loaded into the first n-type doping satellite chamber and the growth is started. When the growth in the first n-type doping satellite chamber has proceeded about a half of the whole growth time in this chamber, another batch of wafers is loaded into the second n-type doping satellite chamber and the growth is started. When the growth process is finished in the first n-type doping satellite chamber, the batch of the finished wafers is transferred to the main chamber and the growth in the main chamber is started. At the same time, a new batch of wafers is loaded into the first n-type doping satellite chamber, and the growth process is started again. Since the time when the growth started again in the first n-type doping satellite chamber with the new batch of wafers corresponds roughly to the time when the growth in the second n-type doping satellite chamber has proceeded about a half of the whole growth time, the same procedure employed in the previous step, which is the discharge and transfer of a batch of grown wafers from the first n-type doping satellite chamber to the main chamber and recharging of a batch of wafers to that n-type doping satellite chamber, can be repeated in a similar pattern for the second n-type doping satellite chamber. Since the time when the growth process is finished in the second n-type doping satellite chamber roughly corresponds to the time when the growth process in the main chamber is finished, when the growth in the main chamber is finished, the batch of the wafers grown in the main chamber is transferred to the p-type doping satellite chamber and then the batch of the wafers grown in the second n-type doping satellite chamber is transferred to the main chamber and the growth is started again in each of the chambers. In this way, batch of wafers can be transferred from the n-type doping satellite chambers, and to the main chamber, and then to the p-type doping satellite chamber in sequence without much of idling of any of the growth chambers while the main chamber receives a batch of wafers from two n-type doping satellite chambers alternatively.

Since the major part of GaN layer in the GaN-based LEDs is grown in the first part of the whole growth process where the undoped GaN and n-type doped GaN are grown and these layers are grown in the n-type doping satellite chamber in this invention, most of the particles are formed in the n-type doping satellite chamber and only a small amount of particles are formed in the main and p-type doping satellite chambers. Therefore, most of the cleaning process is performed on n-type doping satellite chambers and the cleaning of the main and p-type doping satellite chamber can be kept to a minimum. The reduction in the number of chamber opening and thus the time the inside of the chamber being exposed to the air reduces the chance for the reactants deposited on various parts inside of the chamber to be oxidized and thus be contaminated for the main and p-type doping satellite chambers.

Furthermore, multiple numbers of n-type doping satellite chambers guarantees the highest running time of the system for producing wafers. For example, when three n-type doping satellite chambers are installed, one n-type doping satellite chamber can be cleaned while the remaining two n-type doping satellite chambers are being operated to produce wafers. Three n-type doping satellite can take turns for cleaning one by one while two of the chambers are always being operated to produce wafers. This method minimizes the halt of the system in producing wafers.

Meanwhile, two wafer transfer chambers are installed in this invention: One between the n-type doping satellite chamber and the main chamber and the other between the main chamber and the p-type doping satellite chamber. The separate wafer transfer chamber reduces the likelihood of cross-contamination through the shared robot and the shared wafer transfer chamber as in the disclosed methods described above.

Furthermore, the n-type doping satellite chambers, the first wafer transfer chamber, the main chamber, the second wafer transfer chamber and the p-type doping satellite chamber are configured to allow for the wafers to be transferred only in the forward direction but not in the reverse direction unless specifically desired. With this scheme, the contamination of growing layers by residual doping reactants can be kept to a minimum.

In order to effectively exploit the merits of the present invention, each of the n-type doping satellite chambers, the main chamber, and the p-type doping satellite chambers are equipped with supply lines through which gallium (Ga), indium (In), aluminum (Al), ammonia (NH₃), n-type doping components (e.g., silicon (Si)), and p-type doping components (e.g., magnesium (Mg)) are supplied.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a cross-sectional view of a semiconductor device grown using a metal organic chemical vapor deposition (MOCVD) apparatus according to an exemplary embodiment of the present invention;

FIG. 2 is a construction diagram of an MOCVD apparatus according to an exemplary embodiment of the present invention; and

FIG. 3 is a construction diagram of an MOCVD apparatus according to another exemplary embodiment of the present invention.

### DETAILED DESCRIPTION OF EXEMPLARY EMBODIMENTS

Exemplary embodiments of the present invention will be described in detail below with reference to the accompanying drawings. While the present invention is shown and described in connection with exemplary embodiments thereof, it will be apparent to those skilled in the art that various modifications can be made without departing from the spirit and scope of the invention.

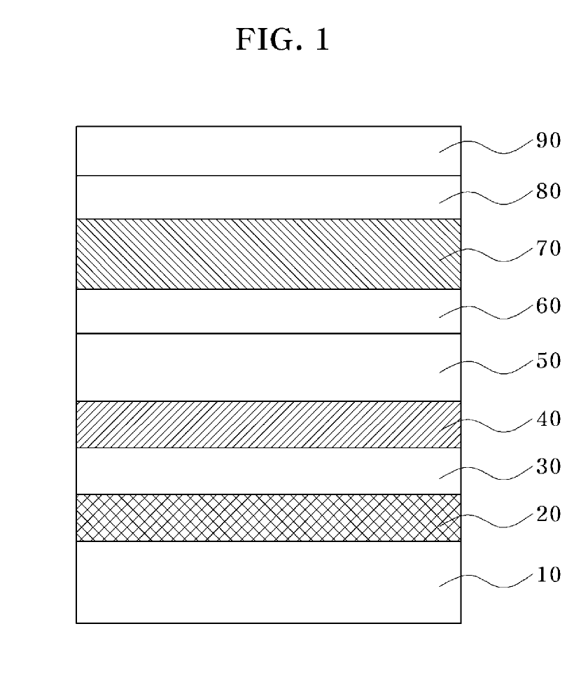

FIG. 1 is a cross-sectional view of a semiconductor device grown using a metal organic chemical vapor deposition (MOCVD) apparatus according to an exemplary embodiment of the present invention.

Referring to FIG. 1, a typical GaN-based LED epitaxial structure includes, for example, a buffer layer 20 initially grown on a substrate 10, such as a sapphire substrate, a GaN substrate, or a silicon (Si) substrate. Next, an n-type GaN layer 30 is grown on buffer layer 20. When the n-type GaN layer is grown on sapphire substrate, which is the most widely used as a substrate, the n-type GaN layer is grown to the thickness of about 3 to 6 μm.

In some cases, a structure with multiple layers or a superlattice of GaN-based materials such as InGaN—AlGaN, AlGaN—GaN, or InGaN—GaN, may be grown in the middle of the n-type GaN layer.

In this case, the n-type GaN layer 30 may be grown on the buffer layer 20, and the n-type doped multiple layer structure (or a superlattice) 40 and the n-type GaN layer 50 may be grown sequentially on the n-type GaN layer 30. Thereafter, the undoped or n-doped GaN layer 60 is grown on n-type GaN layer 50, and the active layer 70 is grown thereon.

The active layer 70 may be a single layer, a single quantum well (SQW) formed of a well and a barrier, an MQW layer, superlattices, or a combination of these structures thereof. The active layer 70 may be undoped or a portion of it may be doped as n-type or p-type. For example, some of the barriers of the QW structure may be doped as n-type or p-type. The QW itself may also be doped as n-type or p-type.

The AlGaN layer 80 and the GaN layer 90 are sequentially grown on top of the QW structure. Although the AlGaN layer 80 and the GaN layer 90 are typically doped as p-type, the doping concentration in them may be partially varied.

In some cases, superlattices may be inserted into some part in the AlGaN layer 80 and the GaN layer 90.

For example, after the p-type GaN layer or AlGaN is grown, p-type doped or partially p-type doped AlGaN—InGaN superlattices may be grown on. Subsequently, p-type doped GaN layer is grown on the resultant structure.

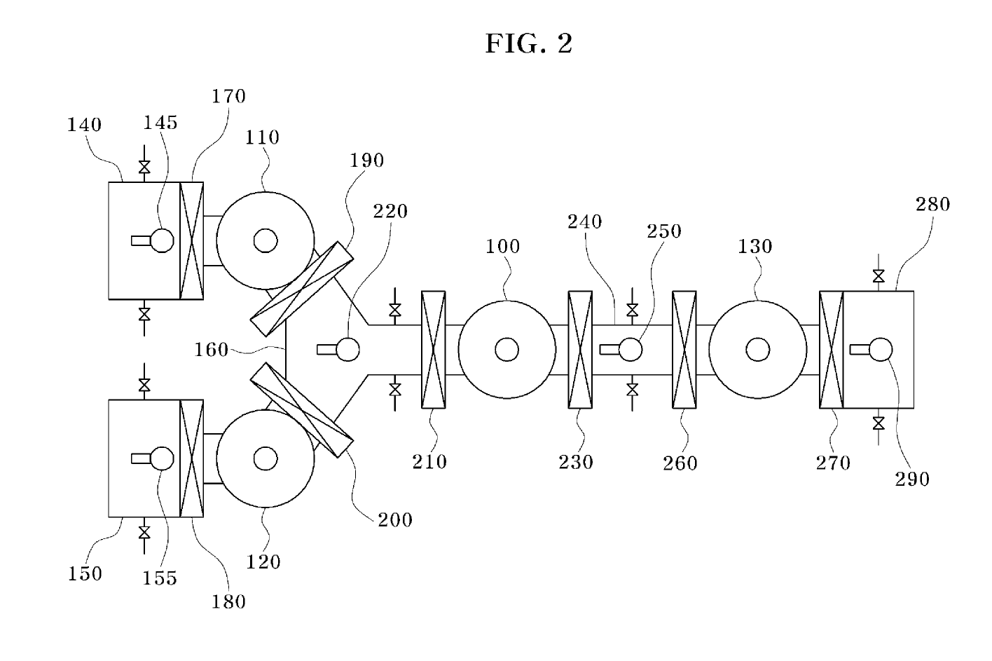

FIG. 2 is a construction diagram of an MOCVD apparatus according to an exemplary embodiment of the present invention.

Referring to FIG. 2, in order to grow the above-described LED structure of FIG. 1, an MOCVD apparatus, according to an exemplary embodiment of the present invention, is equipped with a main chamber 100, the first and the second n-type doping satellite chambers 110 and 120, and a p-type doping satellite chamber 130.

Referring to the semiconductor structure of FIG. 1, the n-type GaN layer 30, the n-type doped multiple layer structure or superlattices 40, the n-type GaN layer 50 are grown in the n-type doping satellite chambers 110 and 120, and the undoped or n-type doped GaN layer 60 and the active layer 70 are grown in the main chamber 100, and the p-type AlGaN layer 80 and the GaN layer 90 are grown in the p-type doping satellite chamber 130.

The main chamber 100 is used mainly to grow the active layer positioned between the n-type doped layer and the p-type doped layer. Just before the active layer 70 is grown, a thin layer of undoped or n-doped GaN 60 is grown. The main chamber 100 is connected to each of the first and the second n-type doping satellite chambers 110 and 120 through the wafer transfer chamber 160. The valves 190 and 200 capable of being opened and closed are installed between the wafer transfer chamber 160 and the first and the second n-type doping satellite chambers 110 and 120, respectively.

The valve 210 capable of being opened or closed is installed between the wafer transfer chamber 160 and the main chamber 100, and a robot 220 which is equipped with multiple robot-arms and configured to transfer wafers, is installed in the wafer transfer chamber 160.

The first and the second load-lock chambers 140 and 150, which are configured to store wafers, are connected to the first and second n-type doping satellite chambers 110 and 120, respectively.

The valves 170 and 180 capable of being opened and closed are installed between the first and the second load-lock chambers 140 and 150 and the first and the second n-type doping satellite chambers 110 and 120, respectively. Robots 145 and 155, which are equipped with multiple robot-arms and configured to transfer wafers, are installed in the first and the second load-lock chambers 140 and 150, respectively.

The main chamber 100 is connected to the p-type doping satellite chamber 130 by a wafer transfer chamber 240. The valve 230 capable of being opened or closed is installed between the main chamber 100 and the wafer transfer chamber 240. The valve 260 capable of being opened or closed is installed between the wafer transfer chamber 240 and the p-type doping satellite chamber 130. The robot 250, which is equipped with multiple robot-arms and configured to transfer wafers, is installed in the wafer transfer chamber 240.

The p-type doping satellite chamber 130 is connected to the third load-lock chamber 280, which is configured to store wafers for which the growth process of the planned layers is finished, through a valve 270. The robot 290, which is equipped with multiple robot-arms and configured to transfer wafers, is installed in the third load-lock chamber 280.

Hereinafter, the operation of the MOCVD apparatus of the present invention for producing wafers for a semiconductor device (i.e., GaN-based LED) according to an exemplary embodiment will be described in detail.

To begin with, the first batch of wafers is loaded into the first load-lock chamber 140, and then transferred to the first n-type doping satellite chamber 110 by robot 145. Thereafter, the buffer layer 20, the n-type GaN layer 30, the multiple-layer structure (or superlattices) 40, and the n-type GaN layer 50 are grown one after another.

The second batch of wafers is loaded into the second n-type doping satellite chamber 120 through the second load-lock chamber 150. After about a half of the time planned for the growth in the first n-type doping satellite chamber 110 has elapsed, the growth in the second n-type doping satellite chamber is started to grow layers 20, 30, 40, and 50 in sequence as in FIG. 1.

After all the planned layers are grown in the first n-type doping satellite chamber 110, the flow of reactants is terminated in the first n-type doping satellite chamber 110.

Next, the first n-type doping satellite chamber 110 is purged with non-oxidizing gases such as ammonia (NH₃), hydrogen, nitrogen, inert gas, or some mixtures thereof, in order to purge out the reactants from the first n-type doping satellite chamber 110 as much as possible.

Meanwhile, the same or similar purge gas, as described above, is supplied into the wafer transfer chamber 160 through the valves installed. When the n-type doping satellite chamber 110 is purged enough, the valve 190 is opened while the valves 200 and 210 are closed. The amount of purge gas supplied into the wafer transfer chamber 160 is controlled so that the purge gas flows from the wafer transfer chamber 160 to the first n-type doping satellite chamber 110 to prevent the reactant gases remaining in the first n-type doping satellite chamber 110 from flowing to the wafer transfer chamber 160.

The purging of the wafer transfer chamber 160 using the above-described gases is performed to prevent the wafer from being exposed to oxidation environments such as the air.

The robot-arms of robot 220 are inserted into the first n-type doping satellite chamber 110 to remove the wafers from the first n-type doping satellite chamber 110. After all the wafers on the wafer-carrier are picked up and taken out of the chamber 110 by the robot-arms, the valve 190 is closed. After that, the valve 210 is opened to transfer wafers to the main chamber 100. The amount of purge gas supplied into the wafer transfer chamber 160 is controlled so that the purge gas flows from the wafer transfer chamber 160 to the main chamber 100 to prevent the reactant gases remaining in the main chamber 100 from flowing to the wafer transfer chamber 160.

Then the robot-arms of the robot 220 reach to the main chamber 100 and the wafers, which had been picked up by the robot arms, are released and loaded on the wafer-carrier installed in the main chamber 100.

The procedure described above for transferring wafers from the n-type doping satellite chamber to the main chamber is to minimize the possibility for the transfer chamber 220 being contaminated by the reactants remaining in the growth chambers which in turn minimize the cross-contamination between the n-type doping satellite chamber 110 and the main chamber 100.

When all the wafers are loaded on the main chamber 100, the valve 210 is closed and the growth in the main chamber is started to grow planned layers (refer to 60 and 70 of FIG. 1) on the wafers. Depending on the layer structure and doping type of the planned layers, the n-type doping growth process and/or the p-type doping growth process can also be performed in the main chamber 100. For example, if some of the layers in the MQW are planned to be doped either in n-type or in p-type, the doping growth is performed in the main chamber 100 instead of sending the wafers back to the n-type doping satellite chamber or to the p-type doping satellite chamber. In this case, even though the n-type or p-type doping growth is performed in the main chamber, the growth time for the doping process is generally short and the amount of doping reactants supplied is generally small so that the contamination of the inside of the main chamber by doping reactants can be kept to a minimum.

When the transfer of the wafers from the first n-type doping satellite 110 to the wafer transfer chamber 160 is completed and the valve 190 is closed, the third batch of wafers is loaded into the first n-type doping satellite chamber 110 and the growth of the layers 20, 30, 40, and 50 in sequence is started.

When the growth of the planned layers in the main chamber 100 is finished, the flow of the reactants is terminated and the chamber is purged. Meanwhile, the purge gas is started to flow into the wafer transfer chamber 240. When the main chamber 100 is purged enough, the valve 230 is opened and the flow though the wafer transfer chamber 240 is controlled so that the purge gas flows from the wafer transfer chamber 240 to the main chamber 100 to prevent the reactant gases remaining in the main chamber 100 from flowing to the wafer transfer chamber 240. Then the wafers in the main chamber are picked up by robot-arms of robot 250 and taken out to the wafer transfer chamber 240.

When the transfer of the wafers to the wafer transfer chamber 240 is finished, the valve 230 is closed and the valve 260 is opened. The amount of purge gas supplied into the wafer transfer chamber 240 is controlled so that the purge gas flows from the wafer transfer chamber 240 to the p-type doping satellite chamber 130 to prevent the reactant gases remaining in the p-type doping satellite chamber 130 from flowing to the wafer transfer chamber 240. Then the robot-arms of robot 250 reach to the p-type doping satellite chamber 130 and the wafers, which had been picked up by the robot arms, are released and loaded on the wafer-carrier installed in the p-type doping satellite chamber 130. After all the wafers are loaded into the p-type doping satellite chamber 130, the valve 260 is closed and the growth in the p-type chamber is started to grow planned layers (refer to 80 and 90 of FIG. 1).

When the growth in the second n-type doping satellite chamber 120 is finished, the wafers are transferred to the wafer transfer chamber 160, and then transferred to the main chamber 100 in a similar manner as the procedure used for transferring wafers from the first n-type doping satellite chamber 110 to the main chamber 100 described above.

After the transfer of the second batch of wafers from the second n-type doping satellite chamber 120 to the main chamber 100 is completed, the growth in the main chamber is started. Then, the fourth batch of wafers is loaded into the second n-type doping satellite chamber 120 and the growth is started.

When the growth in the p-type doping satellite chamber 130 is completed, the wafers are cooled down to the planned temperature and then transferred to the third load-lock chamber 280 by the robot 290.

The alternate loading of wafers between the first n-type doping satellite chamber and the second n-type doping satellite chamber in a predetermined time interval as described above maximizes the usage of the whole growth chambers and thus maximizes the productivity of system.

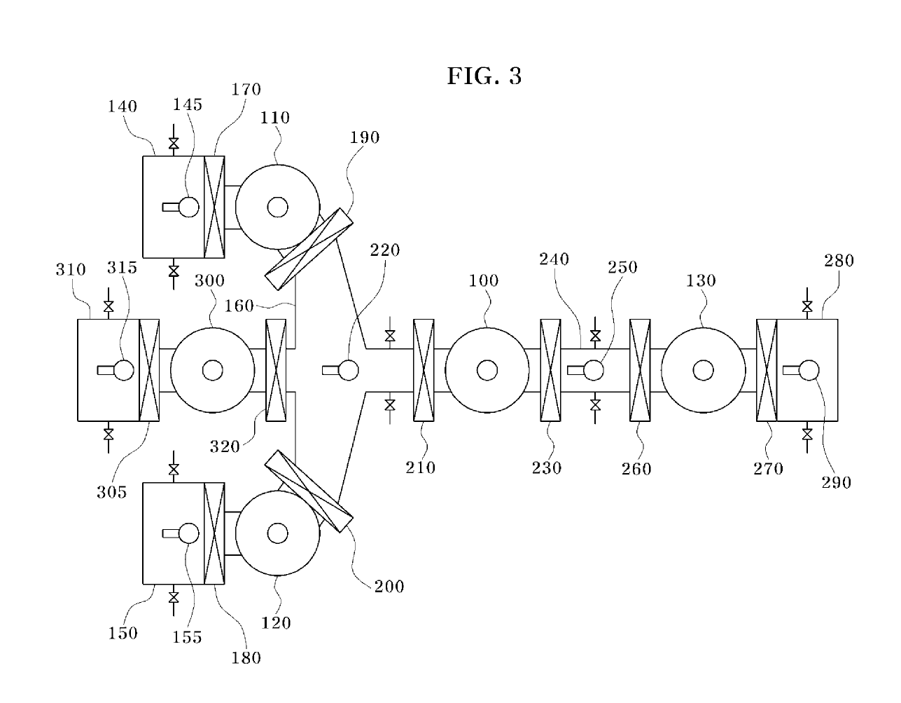

FIG. 3 is a construction diagram of an MOCVD apparatus according to another exemplary embodiment of the present invention.

Referring to FIG. 3, the MOCVD apparatus according to another exemplary embodiment includes a third n-type doping satellite chamber 300 in addition to the chambers described in FIG. 2.

With the third n-type doping satellite chamber 300 added, the fourth load-lock chamber 310, which is equipped with a robot 315 with multiple robot-arms and configured to store wafers, is installed.

The procedure for the loading of wafers to the n-type doping satellite chamber 300 and transferring of wafers from the n-type doping satellite chamber 300 to the main chamber 100 is similar to the procedures described above for that between the n-type doping satellite chamber 110 and the main chamber 100 and between the n-type doping satellite chamber 120 and the main chamber 100.

With three n-type doping satellite chambers installed, one of three satellite chambers can be allocated for cleaning or maintenance processes while two chambers are used for growing wafers. In this way, the growth is not interrupted even when one n-type doping satellite chamber is removed from the wafer production line as long as the main chamber 100 and the p-type doping satellite chamber 130 are in operation. This provides an advantage over the configuration in FIG. 2 where the wafer production process is slowed down when one of two n-type doping satellite chamber is being cleaned since the growth time in the n-type doping satellite chamber is generally the longest for the growth of GaN-based LEDs and thus the main chamber should wait until the growth in the n-type doping satellite chamber is finished and the wafers are transferred to the main chamber even when the growth in the main chamber has finished earlier.

The three doping satellite chambers 110, 120, and 300 can take turns for chamber cleaning and maintenance processes, thereby the production of wafers from the system is continued at the maximum speed the configuration provides until the growth in the main chamber 100 or the p-type doping satellite chamber 130 is stopped for chamber cleaning and maintenance. It is because, with the configuration of growth procedure being employed in this invention, the interval between two cleaning-and-maintenance processes for the main and p-type doping satellite chamber is much longer than that for n-type doping satellite chamber since the thickness of GaN that are grown in these chambers is much smaller and thus the particle generation is much smaller.

As described above, the MOCVD apparatus of the present invention minimizes the contamination of growing layers by residual doping reactants deposited inside of the chamber and maintain high productivity of wafers by minimizing the interruption of wafer production by chamber cleaning and maintenance processes.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

What is claimed is:

1. A metal organic chemical vapor deposition (MOCVD) apparatus, comprising:
Multiple numbers of first-doping-type satellite chambers configured to grow the first-doping-type semiconductor layer on a wafer for fabricating a semiconductor device;
a first wafer transfer chamber connected to the first-doping-type satellite chambers, and is equipped with robot configured to transfer wafers;
a main chamber connected to the first wafer transfer chamber, and configured to grow semiconductor layers on the first-doping-type semiconductor layers;
a second wafer transfer chamber connected to the main chamber, and equipped with a robot configured to transfer wafers; and
at least one second-doping-type satellite chamber connected to the second wafer transfer chamber, and configured to grow second-doping-type semiconductor layers on the wafer,
wherein the first-doping-type satellite chambers, the first wafer transfer chamber, the main chamber, the second wafer transfer chamber, and the second-doping-type satellite chamber are configured to allow the wafer to be sequentially transferred only in forward direction during a growth process but not in reverse direction unless specifically planned.

2. The apparatus of claim 1, wherein at least two first-doping-type satellite chambers are provided and each of the first-doping-type satellite chambers perform a growth process and alternatively supply wafers to the main chamber; and
the start of the growth in each of the chambers is timely scheduled so that the growth in each of the first-doping-type satellite chambers is terminated at a regular time interval so that the wafer transfer from each of the first-doping-type satellite chambers to the main chamber alternate at a regular time interval.

3. The apparatus of claim 1, wherein at least three first-doping-type satellite chambers are provided and each of the three first-doping-type satellite chambers perform a growth process and alternatively supply wafers to the main chamber; and
the start of the growth in each of the chambers is timely scheduled so that the growth in each of the first-doping-type satellite chambers is terminated at a regular time interval so that the wafer production is not interrupted by maintenance by assigning two of the first-doping-type satellite chambers for growth while the remaining chamber(s) is allocated for chamber cleaning and maintenance processes.

4. The apparatus of claim 1, wherein the first wafer transfer chamber configured to transfer wafers is connected to the first-doping-type satellite chambers in one direction and to the main chamber in other direction, and
the first wafer transfer chamber is purged with a non-oxidizing purge gas to control the purge gas to flow in a direction from the first wafer transfer chamber to the first-doping-type satellite chambers and to flow in a direction from the first wafer transfer chamber to the main chamber but not in the opposite directions.

5. The apparatus of claim 1, wherein the second wafer transfer chamber configured to transfer the wafer is connected to the main chamber in one direction and to the second-doping-type satellite chamber in other direction, and
the second wafer transfer chamber is purged with a non-oxidizing purge gas to allow the purge gas to flow in a direction from the second wafer transfer chamber to the main chamber and to flow in a direction from the second wafer transfer chamber to the second-doping-type satellite chamber but not in opposite directions.

6. The apparatus of claim 1, further comprising multiple numbers of load-lock chambers, each configured to store wafers on which the epitaxial growth process will begin in the main chamber, and are equipped with a robot configured to transfer wafers.

7. The apparatus of claim 1, wherein valves are respectively installed between each of the load-lock chambers and each of the first-doping-type satellite chambers.

8. The apparatus of claim 1, further comprising a load-lock chamber connected to the second-doping-type satellite chamber, configured to store wafers for which the growth process of the planned layers is finished, and are equipped with a robot configured to transfer wafers.

9. The apparatus of claim 1, wherein the semiconductor device is a gallium nitride (GaN)-based light emitting diode (LED) device, and
wherein the first-doping-type semiconductor layer is n-type doped semiconductor layer, and the second-doping-type semiconductor layer is p-type doped semiconductor layer.

10. The apparatus of claim 1, wherein valves are respectively installed between the main chamber and the first wafer transfer chamber and between the main chamber and the second wafer transfer chamber.

11. The apparatus of claim 1, wherein the growth time in the main chamber is shorter than the growth time in the first-doping-type semiconductor layer.

12. The apparatus of claim 1, wherein each of the first-doping-type satellite chambers, the main chamber, and the second-doping-type satellite chamber are equipped with supply lines through which gallium (Ga), indium (In), aluminum (Al), ammonia (NH₃), and reactants of n-type and p-type doping components are supplied.
